(19) United States
(12) Patent Application Publication
(10) Pub. No.: US 2017/0317305 A1
(43) Pub. Date: Nov. 2, 2017

(54) SYSTEMS AND METHODS FOR TRANSPARENT ORGANIC PHOTOVOLTAIC DEVICES

(71) Applicant: SolarWindow Technologies, Inc., Columbia, MD (US)

(72) Inventors: Scott R. Hammond, Wheat Ridge, CO (US); John A. Conklin, Apalachin, NY (US)

(21) Appl. No.: 15/141,524

(22) Filed: Apr. 28, 2016

(51) Int. Cl. H01L 51/44; H01L 51/00

(52) U.S. Cl. CPC H01L 51/448; H01L 51/0023; H01L 51/445

(57) ABSTRACT

Systems and methods for transparent organic photovoltaic devices are provided. In one embodiment, an organic semiconductor device comprises: a first glass sheet comprising a first ultra-thin flexible glass material; at least one transparent organic photovoltaic cell bound to the first glass sheet; and a second glass sheet applied to the at least one organic photovoltaic cell, wherein the at least one transparent organic photovoltaic cell is positioned between the first glass sheet and the second glass sheet.

### BACKGROUND

Semi-transparent organic semiconductor devices have the characteristic of allowing at least some light in the spectrum of visible light to pass completely through the device. For many semi-transparent semiconductor devices, it is desired to have as much visible light as possible pass completely through the device so that it appears to human beings as either transparent, or mostly transparent with only a moderate visible tint. Industry has specifically expressed interest in semi-transparent organic photovoltaic devices, which may be innocuously used in conjunction with glass windows or other building components to avoid installation of unsightly traditional photovoltaic array systems. However, retrofitting of existing building windows with semi-transparent organic photovoltaic devices can be challenging.

For the reasons stated above and for other reasons stated below which will become apparent to those skilled in the art upon reading and understanding the specification, there is a need in the art for flexible transparent organic photovoltaic devices.

### SUMMARY

The embodiments of the present disclosure provide methods and systems for flexible transparent organic photovoltaic devices and will be understood by reading and studying the following specification.

Systems and methods for transparent organic photovoltaic devices are provided. In one embodiment, an organic semiconductor device comprises: a first glass sheet comprising a first ultra-thin flexible glass material; at least one transparent organic photovoltaic cell bound to the first glass sheet; and a second glass sheet applied to the at least one organic photovoltaic cell, wherein the at least one transparent organic photovoltaic cell is positioned between the first glass sheet and the second glass sheet.

### DRAWINGS

Embodiments of the present disclosure can be more easily understood and further advantages and uses thereof more readily apparent, when considered in view of the description of the preferred embodiments and the following figures in which:

FIG. 1 is a diagram illustrating a cross-sectional view of a flexible transparent OPV module of one embodiment of the present disclosure;

FIGS. 1A and 1B illustrate embodiments of laminated flexible glass sheets for use with alternative embodiments of the present disclosure;

FIG. 2 provides an alternative diagram of an example flexible transparent OPV module such as shown in FIG. 1;

FIGS. 3 and 3A illustrate another alternative implementation of the flexible transparent OPV module of FIG. 1;

FIGS. 4 and 5A-5G illustrate a method 400 of one embodiment of the present disclosure;

FIGS. 6 and 7 are diagrams illustrating insulated glass unit (IGU) that incorporate an integrated flexible transparent OPV module of one embodiment of the present disclosure; and

FIG. 8 is a flow chart illustrating another method of one embodiment of the present disclosure.

In accordance with common practice, the various described features are not drawn to scale but are drawn to emphasize features relevant to the present disclosure. Reference characters denote like elements throughout figures and text.

### DETAILED DESCRIPTION

In the following detailed description, reference is made to the accompanying drawings that form a part hereof, and in which are shown specific illustrative examples in which embodiments may be practiced. These embodiments are described in sufficient detail to enable those skilled in the art to practice the described embodiments, and it is to be understood that other embodiments may be utilized and that logical, mechanical and electrical changes may be made without departing from the scope of the embodiments of the present disclosure. The following detailed description is, therefore, not to be taken in a limiting sense.

Embodiments of the present disclosure provide transparent organic photovoltaic devices that comprise one or more transparent organic photovoltaic cells secured to at least one sheet of ultra-thin flexible glass material. In some embodiments, the transparent organic photovoltaic cells may be positioned between two opposing sheets of ultra-thin flexible glass material. Unlike organic photovoltaic cells fabricated on rigid substrates, embodiments of transparent organic photovoltaic devices described herein can be fabricated using roll-to-roll processing. Further, the flexible transparent organic photovoltaic devices may be incorporated into rolls of film that are easily transported to installation sites and applied to existing windows or other structural surfaces. As the term is used herein, a device or layer that is referred to as “transparent” or “semi-transparent” means that at least some quantity of photons visible to human beings (generally considered to be light in the wavelength range of approximately 380 nm to 680 nm) completely penetrate through the device or layer without being absorbed. The term “Visible Light Transmission” or “VLT” refers to the percent of photons having wavelengths falling within the visible light spectrum that pass through a device or layer without being absorbed. Referring to an element as semi-transparent implies that the element has a VLT of less than 100% across the Visible Light Spectrum, but greater than 0%. It should be appreciated that the designation of “front” and “back” sides for a semitransparent organic semiconductor device is somewhat arbitrary as light may enter (or leave) from either side. For clarity, as the terms are used herein, the “back” or “bottom” side of a cell will refer to the side comprising a substrate on which the device layers are built, and layers between the active layer and the substrate, the “front” or “top” side will refer to the opposing layers built on top of the active layer.

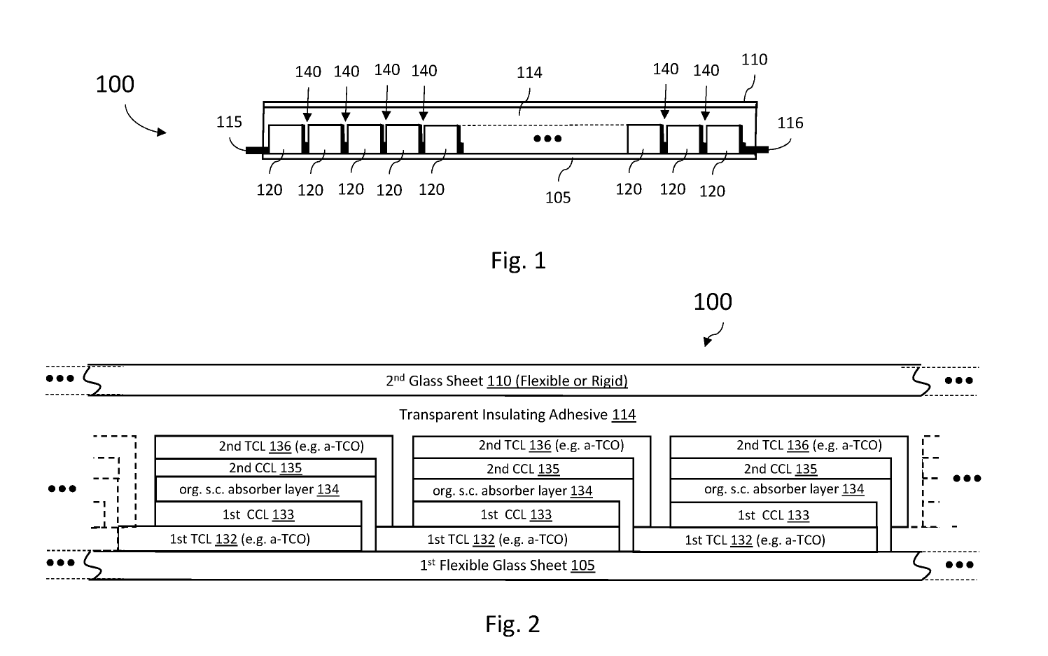

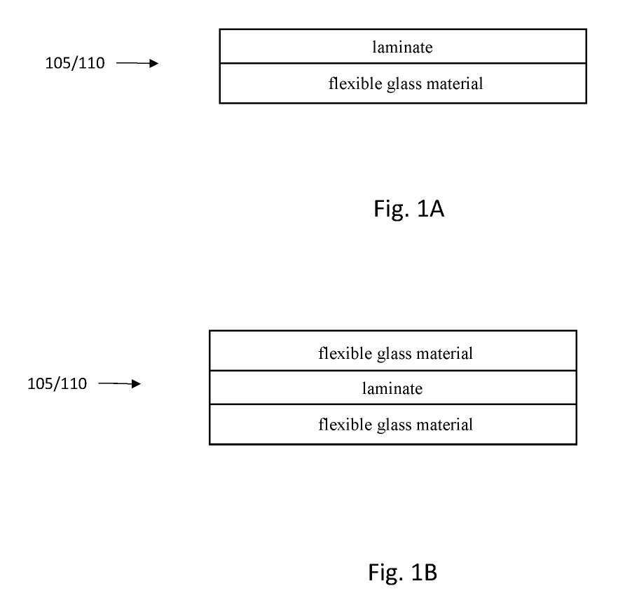

FIG. 1 is a diagram illustrating a cross-sectional view of a transparent OPV module 100 of one embodiment of the present disclosure. Module 100 comprises a plurality of individual OPV cells 120 positioned between a first flexible glass sheet 105 and a second glass sheet 110 that may be either a flexible or a rigid glass sheet. The first flexible glass sheet 105 comprises a common base, or substrate, upon which the plurality of OPV cells 120 are fabricated. As such, the first flexible glass sheet 105 may also be referred to herein a flexible glass substrate 105. The second glass sheet 110 defines the opposing side of device 100 from the first flexible glass sheet 105. Where both the first and second sheets 110 and 105 are flexible glass sheet, module 100 may be considered a flexible transparent OPV module.

Neighboring OPV cells 120 are electrically coupled by electrical interconnects (shown generally at 140). In some embodiments, the electrical interconnects 140 are series interconnects that couple neighboring OPV cells 120 electrically in series. In other embodiments, the electrical interconnects 140 couple neighboring OPV cells 120 are parallel interconnects that electrically couple neighboring OPV cells 120 in parallel. Module 100 may also include negative and positive electrodes 115 and 116 that are electrically connected to the interconnected OPV cells 120 and may be used to electrically connect the module 100 to one or more external devices or systems. Electrodes 115 and 116 may be respectively located at opposite edges of module 100, as shown in FIG. 1. In other embodiments, electrodes 115 and 116 may be co-located on the same edge of module 100. In the embodiment shown in FIG. 1, the second glass sheet 110 is secured to the PV module 100 by a transparent insulating adhesive 114 which may be applied over at least a portion of the plurality of individual OPV cells 120. In other embodiments the second glass sheet 120 may comprise layered laminating foils directly applied over the OPV cells 120 and interconnects 140.

FIG. 2 provides a detailed diagram of flexible transparent OPV module 100 that more particularly illustrates the plurality of device layers that make up the individual OPV cells 120 and module 100. As shown in FIG. 2, each of the individual OPV cells 120 comprise a first transparent contact layer (TCL) 132, a first charge collection layer 133, an organic semiconductor absorber layer 134, a second charge collection layer 135 and a second transparent contact layer 136. In the embodiment shown in FIG. 2, the first charge collection layer 133 is shown as defining an electron collection layer (ECL) while the second charge collection layer 135 is shown as defining a hole collection layer (HCL). It should be appreciated that in other embodiments, the first charge collection layer 133 may instead define a hole collection layer while the second charge collection layer 135 defines an electron collection layer.

As mentioned above, at least the first glass sheet 105 (and in some embodiments, also the second glass sheet 110) comprise an ultra-thin flexible glass material. As the term is used herein, an ultra-thin flexible glass material refers to a glass material that is drawn down to an ultra-thin thickness (generally considered on the order of 200 micron or less, for example) allowing the material to flex to a significant degree. For example, an ultra-thin flexible glass sheet in one implementation has the property that it can be bent to a radius of curvature of 6 inches before it will crack or fail. Despite the thinness of the material, flexible glass retains the other beneficial characteristics of rigid glass with respect to its ability to form a hermetic barrier to oxygen and water diffusion, and its ability to withstand significantly higher temperatures than flexible plastics such as polyethylene terephthalate (PET) and polyethylene naphthalate (PEN). A non-limiting example of a flexible glass material which may be used to realize first and/or second glass sheets 105 and 110 is the Willow Glass® material by Corning Incorporated. In other embodiments, in addition to Willow Glass®, glass sheets 105 and 110 may comprise other ultra-thin flexible glass materials such as from Nippon Electric Glass Co. Ltd., Asahi Glass Co. Ltd., Schott AG, or other sources, or other glass material having flexibility characteristics equivalent to Willow Glass® material by Corning Incorporated.

The first transparent contact layer 132 is often referred to by convention as the bottom or back transparent contact layer because it is adjacent to the substrate 105 upon which the PV cell stack layers are fabricated. In one implementation as illustrated in FIG. 2, this transparent contact layer may comprise a layer of an amorphous transparent conducting oxide (a-TCO) material, such as but not limited to an indium zinc oxide (IZO). Amorphous oxides, as opposed to oxides comprising a crystal lattice structure, are less prone to cracking as a function of bend cycles and therefore more suited for use in flexible photovoltaic device applications. That being said, in other implementations, a crystalline transparent conducting oxide (c-TCO) may be deposited onto substrate 105 to form the first TCL 132. A c-TCO material may be suitable, for example, in applications where the degree of expected device flexing or the expected number of bending cycles will be limited. As such, the first TCL 132 may alternately comprise c-TCOs such as but not limited, indium tin oxide (ITO), Aluminum doped Zinc Oxide (AZO), or Gallium doped Zinc Oxide (GZO). In other embodiments, a high temperature solution process may be used to apply TCL 132 onto substrate 105 rather than a vacuum-sputter process. For example, an a-TCO material such as, but not limited to, a Fluoride-doped Tin Oxide (FTO) may be applied using a chemical solution process to deposit the FTO on the substrate 105. In such embodiments, the high temperature stability of the flexible glass, on the order of 400° C., is favorable when compared to flexible plastics such as PET and PEN that are limited to temperatures of around 150° C.

In alternate embodiments of module 100, either the first charge collection layer 133 or the second charge collection layer 135 will comprise the electron collection layer. The electron collection layer serves as a barrier to holes attempting to flow to the adjacent transparent contact layer while allowing electrons produced in the organic semiconductor absorber layer 134 to flow from into the transparent contact layer 132. In different embodiments, any number of transparent materials as would be known to those of skill in the art of OPV devices may be deposited to form the electron collection layer. However, for the reasons described above, amorphous transparent oxides may be considered particularly well suited for flexible applications. Zinc Oxide (ZnO) is one example of an amorphous transparent oxide material that may be deposited to form an electron collection layer.

Depending on which of the first charge collection layer 133 or the second charge collection layer 135 comprises the electron collection layer, the other chare collection layer will comprise the hole collection layer. The hole collection layer functions as a barrier to electrons attempting to migrate to the adjacent transparent contact layer while at the same time allowing hole charges produced in the absorber layer to flow into that transparent contact layer. During operation of OPV cell 120, light enters into the OPV cells 120 and as a results, the absorber layer 134 generates electron and hole charges from absorbed photons. The resulting collection of opposing charges accumulating in the back contact layer 132 (negative electron charges when layer 133 is an ECL and positive hole charges when layer 133 is a HCL) and front contact layer 136 (positive hole charges when layer 135 is a HCL and negative electron charges when layer 135 is an ECL) manifests a voltage potential across the respective contact layers 132 and 136. Through the electrical interconnects 140 the respective charges propagate to positive and negative electrodes 115 and 116 which may in turn be coupled to one or more electronic devices in order to provide electrical power to the devices, and/or for storage of the energy generated by module 100.

In some embodiments, organic semiconductor absorber layer 134 includes a combination of an electron donor material (which may be a polymer or small molecule) and an electron acceptor material (which may be a fullerene or small molecule or polymer). In some embodiments, the absorber layer 134 comprises a blend of the electron donor material and the electron acceptor material forming a bulk-heterojunction (BHJ). In other embodiment, the absorber layer 134 may be a bilayer organic absorber layer meaning that the acceptor material and donor material are structured as distinct layers.

During the fabrication of each of the OPV cells 120, deposition of the second charge collection layer 135 may also serve as a buffering layer that protects organic semiconductor absorber layer 134 during deposition of subsequent device layers. For example, the second charge collection layer 135 may function as a buffering charge collection layer that protects the organic semiconductor absorber layer 134 from damage during sputter-deposition of the second transparent contact layer 136. This is, it is generally known that ion bombardment during a sputtering process will damage polymers in an organic semiconductor active layer to the point that the active layer is no longer operable as an electronic device. Application of a buffering charge collection layer of sufficient thickness to operate as a hole or electron collection layer will result in a buffer of sufficient thickness to also protect the organic semiconductor absorber layer 134 from ion bombardment damage, for example, during a sputtering process that may be used to deposit the transparent contact layer 136.

Any number of transparent materials that would be known to those of skill in the art of OPV devices may be deposited to form the hole collection layer. However, for the reasons described above, amorphous transparent oxides may be considered particularly well suited for flexible applications, such as but not limited to tungsten trioxide (WO₃). In other embodiments, the hole collection layer may comprise a transparent conducting polymer such as but not limited to poly(3,4-ethylenedioxythiophene) (PEDOT) which may be blended with a polystyrene sulfonate (PSS) to dope the organic polymer into a more highly conductive state.

It should be appreciated that when the second charge collection layer 135 defines the device's hole collection layer, it is not necessary for the material to be doped with PSS because the front contact layer 136 will serve the purpose of providing a low sheet resistance. In other words, a sputtered a-TCO or c-TCO material deposited onto the charge collection layer 135 can provide a transparent material layer having the desired low sheet resistance so that the sheet resistance of the charge collection layer 135 is not a factor that will affect device operability. In addition to transparent polymers such as PEDOT:PSS, other materials, such as but not limited to transparent oxides may be used as a buffering charge collection layer 135. For example, in one embodiment, the second charge collection layer 135 comprises a metal oxide which may be deposited through evaporative/vapor deposition or solution-processing methods, such as but not limited to tungsten trioxide (WO₃), and which is known to function well as a hole transport layer.

The second transparent contact layer 136 is sometimes referred to by convention as the front or top transparent contact layer because it is positioned on the opposite side of OPC cell 120 from the back substrate (i.e., sheet 105) upon which the device is fabricated. In one embodiment, the second transparent contact layer also comprise a layer of an amorphous transparent conducting oxide (a-TCO) material, such as but not limited to an IZO. As discussed above, the amorphous oxides are less prone to cracking as a function of bend cycles and therefore more suited for use in flexible photovoltaic device applications. That being said, in other embodiments, a crystalline transparent conducting oxide (c-TCO) may be deposited to form the second transparent contact layer 136 for applications where the expected degree of device bending or the number of bending cycles will be limited. In such applications, the second TCL 136 may alternately comprise c-TCOs such as but not limited, indium tin oxide (ITO), Aluminum doped Zinc Oxide (AZO), or Gallium doped Zinc Oxide (GZO).

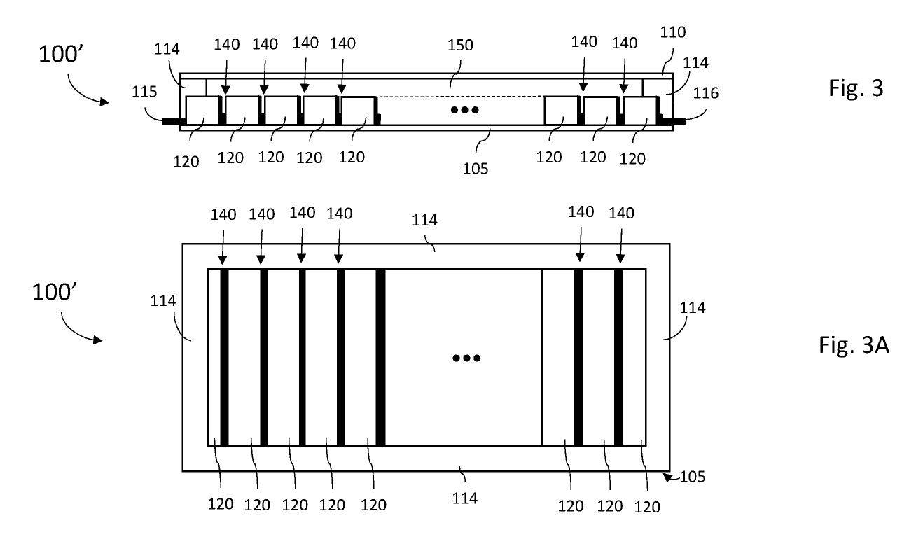

When the second glass sheet 110 is secured using a transparent insulating adhesive 114, this material may comprise an electrically inert and transparent epoxy or other adhesive known to those of skill in the art. Ideally the material should be a material known to not substantially cloud or discolor due to exposure to solar flux. In one embodiment, one or more layers of the transparent insulating adhesive 114 is applied fully over the entirety of the OPV cells 120 and interconnects 140. The second glass sheet 110 is then applied over the transparent insulating adhesive 114 using methods known to those of skill in the art of laminating. In one such embodiment, the volume between the second glass sheet 110 and the PV cells 120 and interconnects 140 is substantially filled with the transparent insulating adhesive 114 (with the exception of any inadvertent voids that may be a natural artifact depending on the lamination method used). In an alternate implementation of module 100 (shown in FIGS. 3 and 3A at 100′) rather than applying the transparent insulating adhesive 114 fully over the entirety of the OPV cells 120 and interconnects 140, it may be applied just around the perimeter edges of the module. The transparent insulating adhesive 114 secures the second glass sheet 110 and hermetically seals the OPV cells 120 and interconnects 140 from the external environment, but at least some portion of the volume between the second glass sheet 110 and the PV cells 120 and interconnects 140 will be open void (shown at 150) rather than filled with the transparent insulating adhesive 114. The combination of the second glass sheet 110 with a transparent conducting oxide front TCL 136 creates an effective oxygen and water diffusion barrier that seals the OPV cells 120 in a hermetic environment. In some embodiments, the exterior facing surface of either one or both of the first and second glass sheets 105, 110 may be further laminated as shown in FIG. 1A using a PET laminate or other material (such as but not limited to a PEN laminate) to further improve the mechanical properties (such as strength) of module 100. Alternatively, as shown in FIG. 1B, either one or both of the first and second glass sheets 105, 110 may comprise laminated flexible glass materials having a PET laminate or other material (such as but not limited to a PEN laminate) sandwiched between ultrathin flexible glass material layers.

It should be appreciated that when module 100 is implemented as a flexible device (i.e., where the first and second glass sheets 105 and 110 are both flexible glass sheets) the full potential bend radius for the module 100 may be reduced as compared to the rated bend radius of either the first or second glass sheets 105 and 110 by themselves. In some embodiments, the materials for the respective first and second glass sheet 105 and 110 may be selected to have slightly different flexibility characteristics to account for slight differences in the bending experienced by each sheet depending on how module 100 flexes. For example, in one embodiment, the first flexible glass sheet 105 may be thicker or thinner than the second flexible glass sheet 110 to accommodate concave flexing of module 100 vs convex flexing of module 100. In other embodiments, the composition of the ultra-thin flexible glass material for the first flexible glass sheet 105 may be different than for a flexible second glass sheet 110 so as to provide a different rated bend radius for the first flexible glass sheet 105 as compared to the second flexible glass sheet 110.

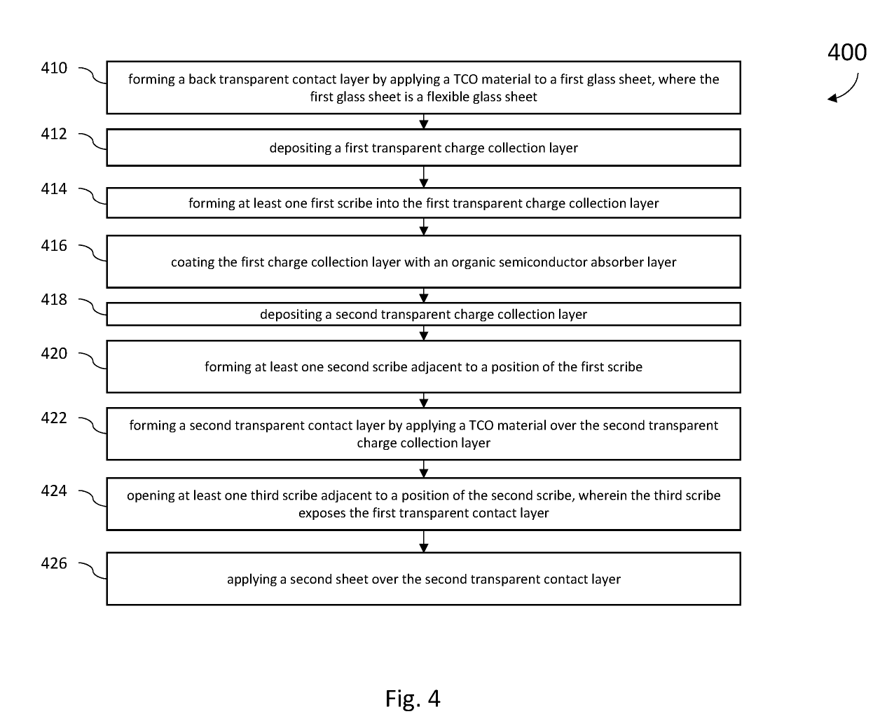

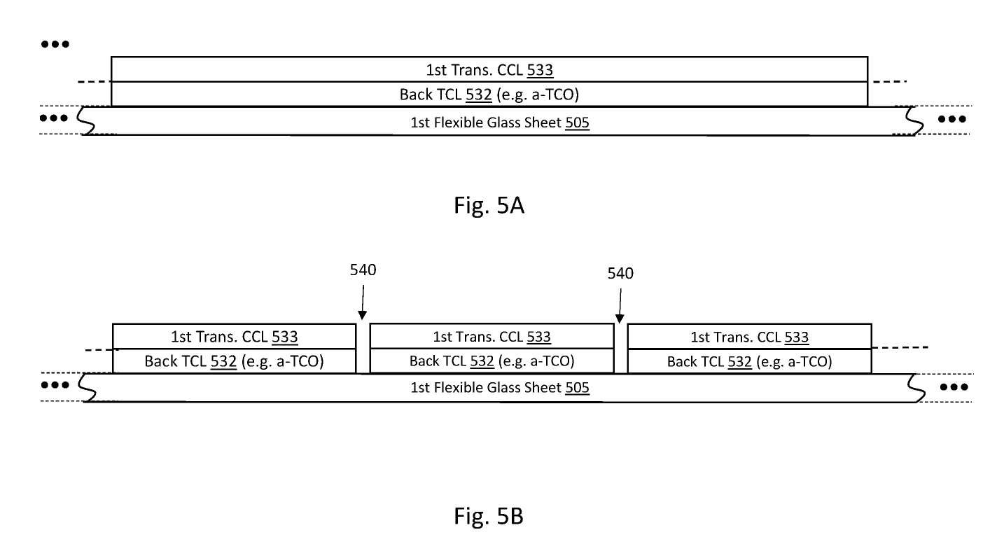

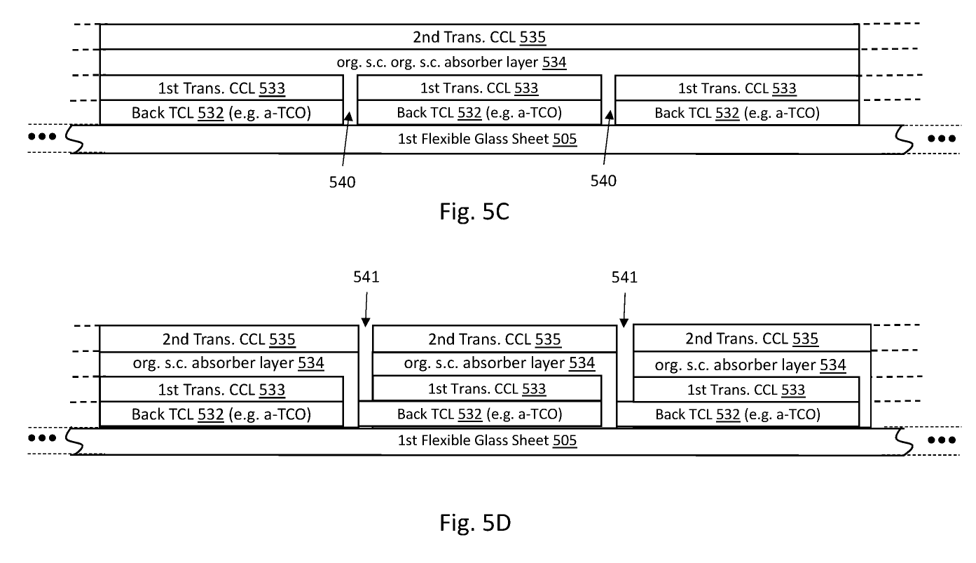

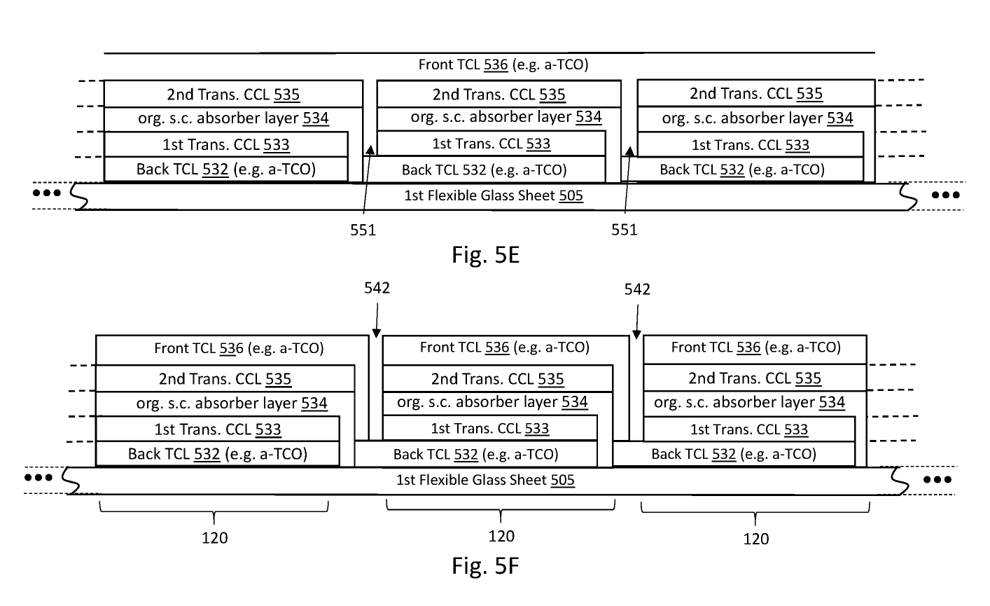

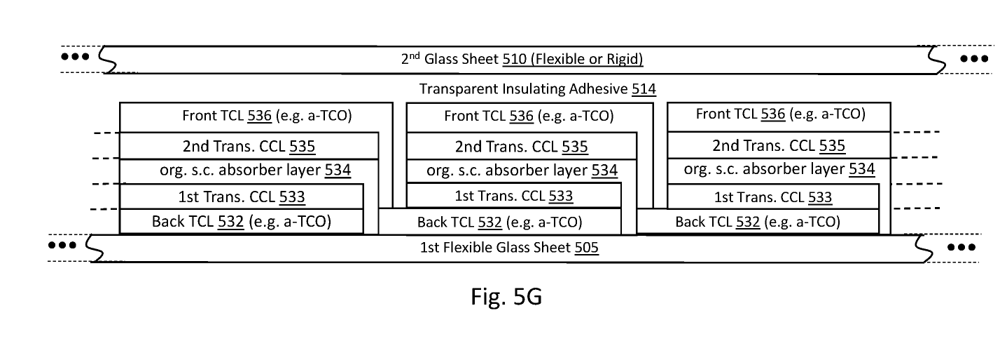

FIG. 4 is a flow chart that illustrates a method 400 of one embodiment of the present disclosure for fabricating a flexible transparent PV module such as illustrated in the accompanying FIGS. 5A-5G. In one implementation, a flexible transparent PV module such as any implementation of a module 100 embodiment described in this disclosure may be fabricated using method 400. It should therefore be understood that elements of method 400 may be used in conjunction with, in combination with, or substituted for elements of those embodiments. Further, the functions, structures and other description of elements for such embodiments described may apply to like named elements of method 400 and vice versa.

Method 400 begins at 410 with forming a back transparent contact layer by applying a TCO material to a first glass sheet, where the first glass sheet is a flexible glass sheet. For example, as shown in FIG. 5A, back TCL 532 (for example, an a-TC) layer) has been deposited over a first flexible glass sheet 505. This deposition may be accomplished by sputtering or other means that are known to those of ordinary skill in the art. As discussed above, amorphous TCOs, as compared to crystalline TCOs, are less prone to cracking as a function of bend cycles and therefore more suited for use in flexible photovoltaic device applications. That being said, in other embodiments, a crystalline transparent conducting oxide (c-TCO) may instead be deposited (by sputtering or other means that are known to those of ordinary skill in the art) to form layer 532. A c-TCO may be appropriate for an application, for example, where device bending or the number of bending cycles will be limited. Although a vacuum-sputter process may be used in some implementations to deposit layer 532, in other implementations a high temperature solution process may instead be used to deposit the TCO 532 onto the first flexible glass sheet 505. For example, an a-TCO material such as, but not limited to, an amorphous formulation of a Fluoride doped Tin Oxide (FTO) may be applied at block 410 using a chemical solution process to deposit the FTO on the first flexible glass sheet 505. As discussed above, the first flexible glass sheet 505 may comprise an ultra-thin flexible glass material.

The method proceeds to 412 with depositing a first transparent charge collection layer, as illustrated in FIG. 5A at 533. In alternate embodiments, depositing the transparent charge collection layer may comprise depositing either an electron or hole collection layer. Selection and deposition of material to form either an electron or hole collection layer at layer 533 are generally within the ordinary skill of the art, however, for the reasons disclosed in this specification, amorphous transparent oxides may be considered particularly well suited for flexible applications, such as but not limited to Zinc Oxide (ZnO) for an ECL or tungsten trioxide (WO₃) for a HCL. In other embodiments, an HCL may also be formed at block 412 using a PEDOT or PEDOT:PSS material.

The method 400 proceeds to 414 with forming at least one first scribe (two of which are shown at 540 in FIG. 5B) into the first transparent charge collection layer 533 and the first transparent contact layer 532. In one embodiment, the first scribe 540 is opened using a laser scribing technique that removes the transparent charge collection layer 533 and transparent contact layer 532 enough to expose the first flexible glass sheet 505. In one embodiment, scribes 540 subdivide the previously deposited layers into segments (such as 1 cm segments, for example). The scribe 540 itself may have a width so that neighboring segment are separated by a distance of 20 to 100 micrometers.

The method proceeds to 416 with coating the first transparent charge collection layer 533 with an organic semiconductor absorber layer 534. As shown in FIG. 5C, the material of the organic semiconductor absorber layer 534 may flow into the open gaps created by the first scribes 540. The organic semiconductor absorber layer 534 includes a combination of an electron donor material (which may be a polymer or small molecule) and an electron acceptor material (which may be a fullerene or small molecule or polymer). In one embodiment, the absorber layer 534 comprises a blend of the electron donor material and the electron acceptor material forming a bulk-heterojunction (BHJ). In other embodiment, the absorber layer 534 may instead be a bilayer organic absorber layer having acceptor material and donor material deposited as distinct layers when performing block 416. Although the material forming the organic semiconductor absorber layer 534 may flow down into the gaps opened by scribes 540, in such a configuration the organic semiconductor material is not well suited to transport charges over such long distances and will therefore serve as an electrical insulator rather than a charge producer or carrier.

The method proceeds to 418 with depositing a second transparent charge collection layer 535 as shown in FIG. 5D. In alternate embodiments, depositing the second transparent charge collection layer 535 may comprise depositing either an electron or hole collection layer, the opposite as whichever was deposited at block 412. That is, if an electron collection layer was deposited at block 412, then a hole transport layer will be deposited at block 418. If a hole collection layer was deposited at block 412, then an electron transport layer will be deposited at block 418. Selection and deposition of materials to form either an electron or hole collection layer at block 418 are generally within the skill of those of ordinary skill in the art. However, for the reasons disclosed in this specification, amorphous transparent oxides are particularly well suited for flexible applications, such as but not limited to Zinc Oxide (ZnO) for an ECL or tungsten trioxide (WO₃) for a HCL. In other embodiments, an HCL may also be formed at block 412 using a PEDOT or PEDOT:PSS material.

The method proceeds to 420 with forming at least one second scribe (two of which are shown at 541 in FIG. 5D) adjacent to a position of the first scribes 540, where the at least one second scribe 541 is opened to a sufficient depth to expose the first transparent contact layer 532. The second scribes 541 may be opened by a mechanical scribe process by first aligning the mechanical scribe tool with the first scribe 540, and then shifting the tool to an adjacent position to perform a mechanical scribe. It should be noted that mechanical scribing on ultra-thin flexible glass materials may induce defects in the first flexible glass sheet 505 and materials deposited onto sheet 505. These defects include fissures or cracks that may later propagate and either degrade or destroy the resulting device. To avoid producing such defects, in one embodiment when performing mechanical scribing at 420, the tip of the mechanical scribe tool may be placed down inside the material layers and lifted up while inside the material layers without either applying or removing the mechanical scribe tool tip beyond the edges of the ultra-thin flexible glass sheet. Alternatively, the second scribes 541 may be formed using a laser scribing method rather than a mechanical scribe process. Using a laser scribing method would permit a smaller scribe size and may reduce induced damage as compared to a mechanical scribe process.

The method next proceeds to 422 with forming a second (front) transparent contact layer 536 by applying a TCO material over the second transparent charge collection layer 535 as shown in FIG. 5E. As shown in FIG. 5E, the material of the second transparent conducting oxide layer 536 may also flow into the gap opened by the second scribes 541. Because the TCO material is an electrical conductor, deposition of the second transparent contact layer 536 will result in the formation of an electrical series interconnect between the second transparent contact layer 536 of one OPV cell and the first transparent contact layer 532 of a neighboring OPV cell. Because the absorber layer 534 material and second transparent contact layer 536 material are both transparent materials, the result is a semitransparent electrical interconnect that passes light through the device as opposed to an opaque interconnect that would block light transmissions. As discussed above, depositing of the second transparent charge collection layer 535 over the absorber layer 534 provides a buffering effect that protects the absorber layer 534 from damage during fabrication processes where the second transparent contact layer 536 is sputter-deposited. In one embodiment, the second transparent contact layer 536 comprise a layer of an amorphous transparent conducting oxide (a-TCO) material, such as but not limited to a sputter-deposited IZO. As discussed above, the amorphous oxides are less prone to cracking as a function of bend cycles and therefore more suited for use in flexible photovoltaic device applications. That being said, in other embodiments, a crystalline transparent conducting oxide (c-TCO) may instead be deposited to form the second transparent contact layer 536 for applications where the expected degree of device bending or the number of bending cycles will be limited. Examples of c-TCOs that may be deposited to form the second transparent contact layer at block 422 include, but are not limited to indium tin oxide (ITO), Aluminum doped Zinc Oxide (AZO), or Gallium doped Zinc Oxide (GZO).

The method 400 proceeds to 424 with opening at least one third scribe 542 adjacent to a position of the second scribes 541(two of which are shown at 541 in FIG. 5F), wherein the third scribe exposes the first transparent contact layer 532. The third scribes 542 may be opened by a laser scribe process by first aligning the laser scribe tool with the second scribe 541, and then shifting the tool to an adjacent position to perform the laser scribe. The third scribes 542 create an insulating gap between neighboring material layers resulting in the plurality of independent OPV cells 120 each electrically connected in series with its neighbor by electrical interconnects 140.

Although method 400 describes formation of electrical interconnects 140 through a series of scribes performed at 414, 420 and 424, it should be appreciated that these particular actions of opening and filling scribes as described above at 414, 420 and 424 are optional in that they provide just one example of a process by which electrical interconnects between OPV cells may be formed. In other embodiments, electrical interconnects may be formed using a different sequence and/or number of scribes or through another technique altogether.

The method 400 proceeds to 426 with applying a second glass sheet 510 over the second transparent contact layer 536. In some embodiments, the second glass sheet 510 comprises a ridged sheet of glass mounted to the second transparent contact layer 536 using a transparent insulating adhesive 514 (as shown in FIG. 5G). In other embodiments, the second glass sheet 510 comprises a flexible glass sheet applied over the second transparent contact layer 536 using a transparent insulating adhesive 514. The transparent insulating adhesive 514 may comprise an electrically inert and transparent epoxy or other adhesive known to those of skill in the art, and ideally should be a material known to not substantially cloud or discolor due to exposure to solar flux. In one embodiment, the transparent insulating adhesive 514 is applied at block 426 fully over the previously deposited device layers with the second flexible glass sheet 510 applied over the transparent insulating adhesive 514 using methods known to those of skill in the art of laminating. In one embodiment the volume between the second flexible glass sheet 510 and previously deposited layers is substantially filled with the transparent insulating adhesive 514, in some implementations including the third scribe 542 openings. In an alternate implementation at block 426, transparent insulating adhesive 514 may instead be applied over a smaller regions, such as just around the perimeter edges. The transparent insulating adhesive 514 secures the second flexible glass sheet 510 and hermetically seals the OPV cells 120 and interconnects 140 from the external environment. The combination of the second glass sheet 510 with a transparent conducting oxide for the second transparent contact layer 536 creates an effective oxygen and water diffusion barrier that seals the OPV cells 120 in a hermetic environment. Further, in still other embodiments, other method besides epoxies or adhesives may be utilized. For example, in one embodiment the second glass sheet 510 is applied over the second transparent contact layer 536 using one or more laminating foils. In some embodiments, the exterior facing surface of either one or both of the first and second glass sheets may be further laminated (such as shown in FIG. 1A) using a PET laminate or other material (such as but not limited to a PEN laminate) to further improve the mechanical properties (such as strength) of the device. Alternatively, such as shown in FIG. 1B, either one or both of the first and second glass sheets may comprise laminated flexible glass materials having a PET laminate or other material (such as but not limited to a PEN laminate) sandwiched between ultrathin flexible glass material layers.

It should be appreciated that the full potential bend radius for a device produced by method 400 may be reduced as compared to the rated bend radius of either the first or second flexible glass sheets by themselves. In some embodiments, the materials for the respective first and second flexible glass sheets may be selected to have different flexibility characteristics to account for slight differences in the bending experienced by each sheet depending on how the device is expected to flex during its lifetime. In one embodiment, the first flexible glass sheet may be thicker or thinner than the second flexible glass sheet to accommodate expected concave flexing vs convex flexing. In other embodiments, the composition of the ultra-thin flexible glass material for the first flexible glass sheet may be different than the second flexible glass sheet so as to provide a different rated bend radius for the first flexible glass sheet as compared to the second flexible glass sheet.

In some embodiments, flexible transparent OPV modules and devices such as flexible transparent OPV modules 100, or devices otherwise produced from method 400, can enable the production of a semi-flexible hermetic device package that can be used as a free standing film for a retrofitting application, such as over the glass panes of installed window units or over other building surfaces where the building owner wants the underlying surface to remain visible. For example, flexible transparent OPV modules such as described herein may be applied to, or otherwise constitute a component of decorative building elements such as tiles or mosaics. Further, as opposed to replacing a window unit, a roll of film comprising a flexible transparent OPV module such as described herein can be rolled up against an existing window and the hermetic nature of the flexible transparent OPV module would help retard water and/or oxygen penetration into that window that would otherwise result in a diminished lifetime. In one embodiment, the film is a free standing film that can be applied directly to the window and secured by a static cling, a pressure sensitive adhesive, or other adhesion means. In one implementation of an external window application, the film is applied so that the back flexible glass sheet interfaces with the outside window surface so that so that sunlight enters the OPV cells through the front side substrate flexible glass sheet because the combination of the front side substrate flexible glass sheet and TCO material of the front side transparent contact layer serve as a superior barrier for inhibiting water and/or oxygen penetration.

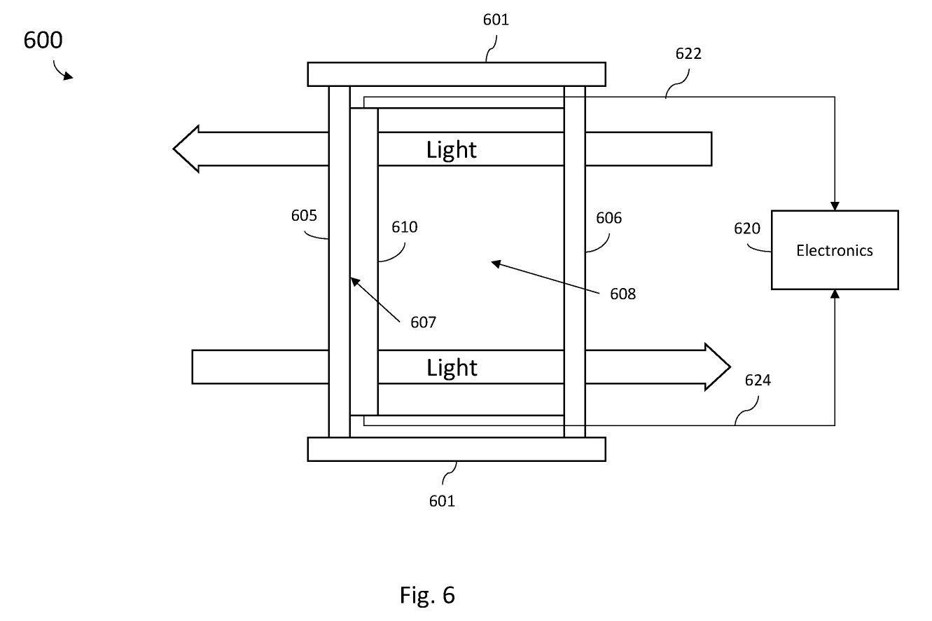

With respect to prefabricated building materials, FIG. 6 is a diagram illustrating a two pane insulated glass unit (IGU) 600 manufactured to include an integrated transparent OPV module 610 within the interior insulating space 608 of the IGU 600. The integrated transparent OPV module 610 may comprise a transparent OPV module such as described with respect to any of the embodiments described above in this disclosure, including module 100 and/or any variation of model 100 described herein. In some embodiments, the integrated transparent OPV module 610 may comprise a flexible glass sheet substrate in combination with a rigid front-side second glass sheet. In other embodiments, both the first (back side) and second (front side) glass sheets are both flexible glass sheets comprising an ultra-thin flexible glass material. In one implementation, the flexible transparent OPV module 610 may be fabricated using method 400. It should also be understood that IGU 600 may be implemented in conjunction with any of the embodiments described above or below. As such, elements of IGU 600 and flexible transparent OPV module 610 may be used in conjunction with, in combination with, or substituted for elements of those embodiments. Further, the functions, structures and other description of elements for such embodiments described may apply to like named elements of IGU 600 and vice versa.

In addition to providing IGU 600 with the capacity to generate photovoltaic electricity, integration of the transparent OPV module 610 effectively boosts the insulating properties of the double-paid IGU 600 without the incremental costs that would be associated with producing IGU 600 as a triple-pane IGU. That is, the integration of transparent OPV module 610 may be used to introduce an additional barrier within IGU to inhibit the through transmission of infrared light and radiant heat.

IGU 600 may be suitable for installation in new construction, or for replacing a previously installed IGU. For example, the interior insulating space of an IGU is often sealed and may comprise and inert gas (such as argon, for example) so that the interior insulating space is thermally insulating and free from moisture. However, since because such seals are imperfect, over time water vapor and air will diffuse from the surrounding environment into the interior insulating space, reducing the IGU's efficiency as a thermal barrier for the building. Such a degraded IGU may be replaced with an IGU having integrated photovoltaic capabilities such as IGU 600.

As shown in FIG. 6, in one embodiment IGU 600 includes a first glass pane 605 and a second glass pane 606 both secured within a frame 601 creating an internal closed space defining the interior insulating space 608. Interior insulating space 608 may be filled to a desired partial pressure with an inert gas having desirable thermal insulating characteristics as would be known to one of ordinary skill in the art. In this embodiment, an integrated transparent OPV module 610 is applied to an inner surface 607 of the first glass pane 605 within the interior insulating space 608. In one embodiment, the first glass pane 605 is designated as the exterior facing side of IGU 600 so that sunlight passes through the transparent OPV module 610 before reaching the interior insulating space 608. In another embodiment, the first glass pane 605 is designated as the interior facing side of IGU 600 so that sunlight passes through the flexible transparent OPV module 610 after passing through the interior insulating space 608. Photovoltaic electricity generated by the transparent OPV module 610 can be transmitted out from the IGU 600 by electrodes 622, 624 which may in turn be coupled to one or more electronic devices 620 in order to provide electrical power to the devices, and/or for storage of the energy generated by module 610.

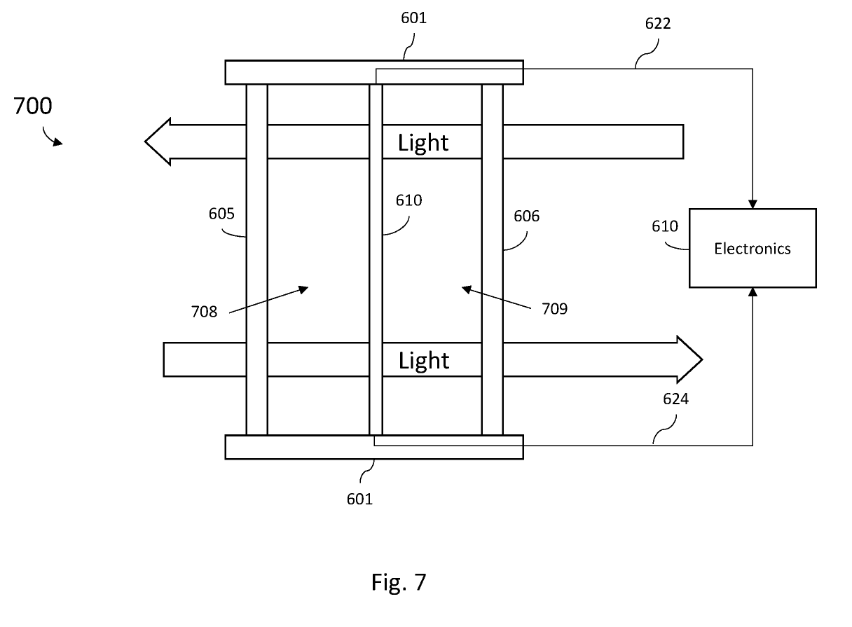

FIG. 7 illustrates IGU 700, which comprises an alternate multi-pane implementation of IGU 600. Similar to IGU 600, IGU 700 includes the first glass pane 605 and second glass pane 606 both secured within a frame 601 creating an internal closed space. In this embodiment, the integrated transparent OPV module 610 defines an independent third pane separated from both the first and second glass panes 605, 606 by independent interior insulating spaces 708 and 709. As described above, in addition to providing IGU 700 with the capacity to generate photovoltaic electricity, integration of the transparent OPV module 610 as an independent third pane effectively boosts the insulating properties of the double-paid IGU 600 without the incremental costs that would be associated with producing IGU 700 with a third pane of rigid glass. The integration of transparent OPV module 610 may be used to introduce an additional barrier within IGU to inhibit the through transmission of infrared light and radiant heat. Further, in this configuration, additional thermal insulating qualities may be realized by having two independent interior insulating spaces 708 and 709.

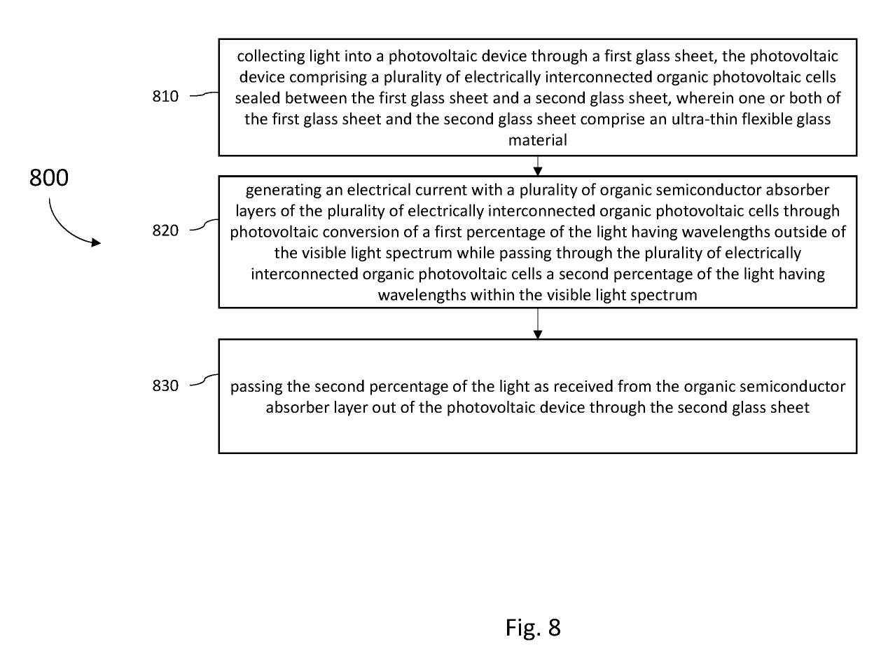

Given the disclosure above, it should be understood that another embodiment flowing from the above described embodiments includes a method for photovoltaic generation of electricity using a transparent OPV device as disclosed from any of the above embodiments. For example, in one embodiment as shown in FIG. 8 at 800, a method comprises: collecting light into a photovoltaic device through a first glass sheet, the photovoltaic device comprising a plurality of electrically interconnected organic photovoltaic cells sealed between the first glass sheet and a second glass sheet, wherein at least one of the first glass sheet or the second glass sheet comprises a flexible glass sheet comprising an ultra-thin flexible glass material (shown at 810). The method proceeds to 820 with generating an electrical current with an plurality of organic semiconductor absorber layers of the plurality of electrically interconnected organic photovoltaic cells through photovoltaic conversion of a first percentage of the light having wavelengths outside of the visible light spectrum while passing through the plurality of organic semiconductor absorber layers a second percentage of the light having wavelengths within the visible light spectrum. The method then proceeds to 830 with passing the second percentage of the light as received from the organic semiconductor absorber layer out of the photovoltaic device through the second glass sheet (shown at 830). It should be understood that method 800 may be implemented in conjunction with any of the embodiments described above with respect to FIGS. 1-7. As such, elements of method 800 may be used in conjunction with, in combination with, or substituted for elements of those embodiments described above. Further, the functions, structures and other description of elements for such embodiments described above may apply to like named elements of method 800 and vice versa.

### Example Embodiments

Example 1 includes an organic semiconductor device, the device comprising: a first glass sheet comprising a first ultra-thin flexible glass material; at least one transparent organic photovoltaic cell bound to the first glass sheet; and a second glass sheet applied to the at least one organic photovoltaic cell, wherein the at least one transparent organic photovoltaic cell is positioned between the first glass sheet and the second glass sheet.

Example 2 includes the device of example 1, further comprising a transparent insulating adhesive applied over the at least one organic photovoltaic cell, wherein the second glass sheet is mounted to the at least one organic photovoltaic cell by the transparent insulating adhesive.

Example 3 includes the device of any of examples 1-2, wherein the second glass sheet comprises a second ultra-thin flexible glass material.

Example 4 includes the device of example 3, wherein the second glass sheet comprises one or more layered laminating foils.

Example 5 includes the device of any of examples 1-4, wherein one or both of the first glass sheet and the second glass sheet comprise a laminated flexible glass material.

Example 6 includes the device of any of examples 1-5, wherein the at least one transparent organic photovoltaic cell comprises a plurality of transparent organic photovoltaic cells coupled by electrical interconnects.

Example 7 includes the device of any of examples 1-6, wherein the first flexible glass sheet and the second flexible glass sheet each comprise an ultra-thin flexible glass material having a thickness of 200 u or less.

Example 8 includes the device of any of examples 1-7, wherein the at least one transparent organic photovoltaic cell comprises: a first transparent contact layer comprising a first transparent conducting oxide applied to the first ultra-thin flexible glass material; a first transparent charge collection layer interfacing with the first transparent contact layer; a second transparent contact layer comprising a second transparent conducting oxide; a second charge collection layer interfacing with the second transparent contact layer; and an organic semiconductor active layer positioned between the first transparent charge collection layer and the second transparent charge collection layer.

Example 9 includes the device of any of examples 1-8, wherein the at least one transparent organic photovoltaic cell each comprise at least one transparent contact layer that comprises an amorphous transparent conducting oxide (a-TCO).

Example 10 includes an organic photovoltaic module, the module comprising: a flexible glass sheet backside substrate comprising an ultra-thin flexible glass material; a plurality of electrically interconnected organic photovoltaic cells bound to the flexible glass sheet; a transparent insulating adhesive applied over the plurality of electrically interconnected organic photovoltaic cells; and a front side glass sheet mounted to the plurality of electrically interconnected organic photovoltaic cells by the transparent insulating adhesive.

Example 11 includes the module of example 10, wherein each of the electrically interconnected organic photovoltaic cells each comprises at least one transparent contact layer that comprises an amorphous transparent conducting oxide (a-TCO).

Example 12 includes the module of any of examples 10-11, wherein flexible glass sheet backside substrate comprises an ultra-thin flexible glass material having a thickness of 200 u or less.

Example 13 includes the module of any of examples 10-12, wherein a first organic photovoltaic cell of the plurality of electrically interconnected organic photovoltaic cells comprises: a first transparent contact layer comprising a first transparent conducting oxide applied to the flexible glass sheet backside substrate; a first transparent charge collection layer interfacing with the first transparent contact layer; a second transparent contact layer comprising a second transparent conducting oxide; a second charge collection layer interfacing with the second transparent contact layer; and an organic semiconductor active layer positioned between the first transparent charge collection layer and the second transparent charge collection layer.

Example 14 includes the module of any of examples 10-13, wherein the second glass sheet comprises a rigid glass sheet.

Example 15 includes an insulated glass unit, the unit comprising: a frame; a first glass pane and a second glass pane both secured within the frame, wherein the first glass pane, the second glass pane, and the frame enclose a volume defining an interior insulating space; and an integrated transparent organic photovoltaic module secured within the interior insulating space; wherein the integrated transparent organic photovoltaic module comprises: a first glass sheet comprising a first ultra-thin flexible glass material; a second glass sheet; and a plurality of electrically interconnected organic photovoltaic cells mounted on the first flexible glass sheet and sealed between the first glass sheet and the second glass sheet.

Example 16 includes the unit of example 15, wherein the second glass sheet comprises a second ultra-thin flexible glass material.

Example 17 includes the unit of any of examples 15-16, wherein the second glass sheet comprises a rigid glass sheet.

Example 18 includes the unit of any of examples 15-17, wherein plurality of electrically interconnected organic photovoltaic cells are sealed between the first flexible glass sheet and the second glass sheet at least in part by a transparent insulating adhesive.

Example 19 includes the unit of any of examples 15-18, wherein the integrated transparent organic photovoltaic module is applied to an inner surface of either the first glass pane or the second glass pane.

Example 20 includes the unit of any of examples 15-19, wherein integrated transparent organic photovoltaic module defines an independent third pane within the interior insulating space separated from both the first glass pane and the second glass pane.

Example 21 includes the unit of any of examples 15-20, wherein the integrated transparent organic photovoltaic module is electrically coupled to at least one electronics device external to the frame.

Example 22 includes the unit of any of examples 15-21, wherein each of the electrically interconnected organic photovoltaic cells each comprise at least one transparent contact layer that comprises an amorphous transparent conducting oxide (a-TCO).

Example 23 includes the unit of any of examples 15-22, wherein the first glass sheet comprises an ultra-thin flexible glass material having a thickness of 200 u or less.

Example 24 includes the unit of any of examples 15-23, wherein a first organic photovoltaic cell of the plurality of electrically interconnected organic photovoltaic cells comprises: a first transparent contact layer comprising a first transparent conducting oxide applied to the flexible glass sheet backside substrate; a first transparent charge collection layer interfacing with the first transparent contact layer; a second transparent contact layer comprising a second transparent conducting oxide; a second charge collection layer interfacing with the second transparent contact layer; and an organic semiconductor active layer positioned between the first transparent charge collection layer and the second transparent charge collection layer.

Example 25 includes the unit of any of examples 15-24, wherein the second glass sheet comprises one or more layered laminating foils applied to the plurality of electrically interconnected organic photovoltaic cells.

Example 26 includes the unit of any of examples 15-25, wherein one or both of the first glass sheet and the second glass sheet comprise a laminated flexible glass material.

Example 27 includes the unit of any of examples 15-26, wherein the at least one transparent organic photovoltaic cell comprises a plurality of transparent organic photovoltaic cells coupled by electrical interconnects.

Example 28 includes the unit of any of examples 15-27, wherein the first glass sheet and the second glass sheet each comprise an ultra-thin flexible glass material having a thickness of 200 u or less.

Example 29 includes the unit of any of examples 15-28, wherein the at least one transparent organic photovoltaic cell comprises: a first transparent contact layer comprising a first transparent conducting oxide applied to the first ultra-thin flexible glass material; a first transparent charge collection layer interfacing with the first transparent contact layer; a second transparent contact layer comprising a second transparent conducting oxide; a second charge collection layer interfacing with the second transparent contact layer; and an organic semiconductor active layer positioned between the first transparent charge collection layer and the second transparent charge collection layer.

Example 30 includes the unit of any of examples 15-29, wherein the at least one transparent organic photovoltaic cell each comprise at least one transparent contact layer that comprises an amorphous transparent conducting oxide (a-TCO).

Example 31 includes a method for photovoltaic generation of electricity, the method comprising: collecting light into a photovoltaic device through a first glass sheet, the photovoltaic device comprising a plurality of electrically interconnected organic photovoltaic cells sealed between the first glass sheet and a second glass sheet; generating an electrical current with a plurality of organic semiconductor absorber layers of the plurality of electrically interconnected organic photovoltaic cells through photovoltaic conversion of a first percentage of the light having wavelengths outside of the visible light spectrum while passing through the plurality of electrically interconnected organic photovoltaic cells a second percentage of the light having wavelengths within the visible light spectrum; and passing the second percentage of the light as received from the organic semiconductor absorber layer out of the photovoltaic device through the second glass sheet; wherein one or both of the first glass sheet and the second glass sheet comprise an ultra-thin flexible glass material.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the embodiments described herein. Therefore, it is manifestly intended that embodiments of the present disclosure be limited only by the claims and the equivalents thereof.

What is claimed is:

1. An organic semiconductor device, the device comprising:
a first glass sheet comprising a first ultra-thin flexible glass material;
at least one transparent organic photovoltaic cell bound to the first glass sheet; and
a second glass sheet applied to the at least one organic photovoltaic cell, wherein the at least one transparent organic photovoltaic cell is positioned between the first glass sheet and the second glass sheet.

2. The device of claim 1, further comprising a transparent insulating adhesive applied over the at least one organic photovoltaic cell, wherein the second glass sheet is mounted to the at least one organic photovoltaic cell by the transparent insulating adhesive.

3. The device of claim 1, wherein the second glass sheet comprises a second ultra-thin flexible glass material.

4. The device of claim 3, wherein the second glass sheet comprises one or more layered laminating foils.

5. The device of claim 1, wherein one or both of the first glass sheet and the second glass sheet comprise a laminated flexible glass material.

6. The device of claim 1, wherein the at least one transparent organic photovoltaic cell comprises a plurality of transparent organic photovoltaic cells coupled by electrical interconnects.

7. The device of claim 1, wherein the first flexible glass sheet and the second flexible glass sheet each comprise an ultra-thin flexible glass material having a thickness of 200 u or less.

8. The device of claim 1, wherein the at least one transparent organic photovoltaic cell comprises:
a first transparent contact layer comprising a first transparent conducting oxide applied to the first ultra-thin flexible glass material;
a first transparent charge collection layer interfacing with the first transparent contact layer;
a second transparent contact layer comprising a second transparent conducting oxide;
a second charge collection layer interfacing with the second transparent contact layer; and
an organic semiconductor active layer positioned between the first transparent charge collection layer and the second transparent charge collection layer.

9. The device of claim 1, wherein the at least one transparent organic photovoltaic cell each comprise at least one transparent contact layer that comprises an amorphous transparent conducting oxide (a-TCO).

10. An organic photovoltaic module, the module comprising:
a flexible glass sheet backside substrate comprising an ultra-thin flexible glass material;
a plurality of electrically interconnected organic photovoltaic cells bound to the flexible glass sheet;
a transparent insulating adhesive applied over the plurality of electrically interconnected organic photovoltaic cells; and
a front side glass sheet mounted to the plurality of electrically interconnected organic photovoltaic cells by the transparent insulating adhesive.

11. The module of claim 10, wherein each of the electrically interconnected organic photovoltaic cells each comprises at least one transparent contact layer that comprises an amorphous transparent conducting oxide (a-TCO).

12. The module of claim 10, wherein flexible glass sheet backside substrate comprises an ultra-thin flexible glass material having a thickness of 200 u or less.

13. The module of claim 10, wherein a first organic photovoltaic cell of the plurality of electrically interconnected organic photovoltaic cells comprises:
a first transparent contact layer comprising a first transparent conducting oxide applied to the flexible glass sheet backside substrate;
a first transparent charge collection layer interfacing with the first transparent contact layer;
a second transparent contact layer comprising a second transparent conducting oxide;
a second charge collection layer interfacing with the second transparent contact layer; and
an organic semiconductor active layer positioned between the first transparent charge collection layer and the second transparent charge collection layer.

14. The module of claim 10, wherein the second glass sheet comprises a rigid glass sheet.

15. An insulated glass unit, the unit comprising:
a frame;
a first glass pane and a second glass pane both secured within the frame, wherein the first glass pane, the second glass pane, and the frame enclose a volume defining an interior insulating space; and
an integrated transparent organic photovoltaic module secured within the interior insulating space;
wherein the integrated transparent organic photovoltaic module comprises:
a first glass sheet comprising a first ultra-thin flexible glass material;
a second glass sheet; and
a plurality of electrically interconnected organic photovoltaic cells mounted on the first flexible glass sheet and sealed between the first glass sheet and the second glass sheet.

16. The unit of claim 15, wherein the second glass sheet comprises a second ultra-thin flexible glass material.

17. The unit of claim 15, wherein the second glass sheet comprises a rigid glass sheet.

18. The unit of claim 15, wherein plurality of electrically interconnected organic photovoltaic cells are sealed between the first flexible glass sheet and the second glass sheet at least in part by a transparent insulating adhesive.

19. The unit of claim 15, wherein the integrated transparent organic photovoltaic module is applied to an inner surface of either the first glass pane or the second glass pane.

20. The unit of claim 15, wherein integrated transparent organic photovoltaic module defines an independent third pane within the interior insulating space separated from both the first glass pane and the second glass pane.

21. The unit of claim 15, wherein the integrated transparent organic photovoltaic module is electrically coupled to at least one electronics device external to the frame.

22. The unit of claim 15, wherein each of the electrically interconnected organic photovoltaic cells each comprise at least one transparent contact layer that comprises an amorphous transparent conducting oxide (a-TCO).

23. The unit of claim 15, wherein the first glass sheet comprises an ultra-thin flexible glass material having a thickness of 200 u or less.

24. The unit of claim 15, wherein a first organic photovoltaic cell of the plurality of electrically interconnected organic photovoltaic cells comprises:
a first transparent contact layer comprising a first transparent conducting oxide applied to the flexible glass sheet backside substrate;
a first transparent charge collection layer interfacing with the first transparent contact layer;
a second transparent contact layer comprising a second transparent conducting oxide;
a second charge collection layer interfacing with the second transparent contact layer; and
an organic semiconductor active layer positioned between the first transparent charge collection layer and the second transparent charge collection layer.

25. The unit of claim 15, wherein the second glass sheet comprises one or more layered laminating foils applied to the plurality of electrically interconnected organic photovoltaic cells.

26. The unit of claim 15, wherein one or both of the first glass sheet and the second glass sheet comprise a laminated flexible glass material.

27. The device of claim 15, wherein the at least one transparent organic photovoltaic cell comprises a plurality of transparent organic photovoltaic cells coupled by electrical interconnects.

28. The unit of claim 15, wherein the first glass sheet and the second glass sheet each comprise an ultra-thin flexible glass material having a thickness of 200 u or less.

29. The unit of claim 15, wherein the at least one transparent organic photovoltaic cell comprises:
a first transparent contact layer comprising a first transparent conducting oxide applied to the first ultra-thin flexible glass material;
a first transparent charge collection layer interfacing with the first transparent contact layer;
a second transparent contact layer comprising a second transparent conducting oxide;
a second charge collection layer interfacing with the second transparent contact layer; and
an organic semiconductor active layer positioned between the first transparent charge collection layer and the second transparent charge collection layer.

30. The unit of claim 15, wherein the at least one transparent organic photovoltaic cell each comprise at least one transparent contact layer that comprises an amorphous transparent conducting oxide (a-TCO).

31. A method for photovoltaic generation of electricity, the method comprising:
collecting light into a photovoltaic device through a first glass sheet, the photovoltaic device comprising a plurality of electrically interconnected organic photovoltaic cells sealed between the first glass sheet and a second glass sheet, wherein one or both of the first glass sheet and the second glass sheet comprise an ultra-thin flexible glass material;
generating an electrical current with a plurality of organic semiconductor absorber layers of the plurality of electrically interconnected organic photovoltaic cells through photovoltaic conversion of a first percentage of the light having wavelengths outside of the visible light spectrum while passing through the plurality of electrically interconnected organic photovoltaic cells a second percentage of the light having wavelengths within the visible light spectrum; and
passing the second percentage of the light as received from the organic semiconductor absorber layer out of the photovoltaic device through the second glass sheet.
